(19) United States
(12) Patent Application Publication
(10) Pub. No.: US 2025/0239443 A1
(43) Pub. Date: Jul. 24, 2025

(54) WORKPIECE PROCESSING METHOD AND PROCESSING APPARATUS

(71) Applicant: DISCO CORPORATION, Tokyo (JP)

(72) Inventor: Kokichi MINATO, Tokyo (JP)

(21) Appl. No.: 19/018,411

(22) Filed: Jan. 13, 2025

(30) Foreign Application Priority Data
Jan. 24, 2024 (JP) 2024-008486

(51) Int. Cl. H01L 21/02; B24B 9/06

(52) U.S. Cl. CPC H01L 21/02016; B24B 9/065; H01L 21/02021

(57) ABSTRACT

A workpiece processing method includes holding a workpiece having a structure in which a first substrate is bonded to a second substrate, such that a side of the second substrate is held by an upper surface of a chuck table, after the holding, forming a trimmed portion along an outer edge of the workpiece by, while causing a ring-shaped cutting blade having an outer peripheral surface and a side surface to rotate, causing the rotating cutting blade to cut into the workpiece along the outer edge of the workpiece from a side of the first substrate to such a depth that the cutting blade reaches the second substrate, the trimmed portion having a bottom surface and a side surface, and polishing the bottom surface and the side surface of the trimmed portion by using a polishing pad.

### BACKGROUND OF THE INVENTION

### Field of the Invention

The present invention relates to a workpiece processing method used to process a workpiece having a structure in which a first substrate is bonded to a second substrate.

### Description of the Related Art

In order to realize device chips that are reduced in size and weight, an increasing number of disk-shaped wafers having devices such as integrated circuits (ICs) formed on a front surface side thereof are processed to be thinned. For example, a wafer is held on a chuck table with its front surface side in contact with the chuck table, and a grinding tool to which a grindstone including abrasive grains is fixed and the chuck table are individually caused to rotate. While liquid such as pure water is supplied, the grindstone of the rotating grinding tool is pressed against a back surface of the wafer held on the rotating chuck table, so that the wafer is ground to be thinned.

A disk-shaped wafer to be used for manufacturing device chips is usually chamfered at an outer edge portion thereof to prevent chipping or breakage of the wafer that can be caused by impact or the like during conveyance of the wafer. However, if the wafer chamfered at the outer edge portion thereof is thinned through grinding or the like, the outer edge portion of the wafer becomes sharp like a knife edge and brittle, which could end up causing chipping or breakage of the wafer.

To cope with this problem, before being ground, the wafer is subjected to processing called edge trimming for removing the portion where chamfering is performed (hereinafter referred to as a chamfered portion) (refer to Japanese Patent Laid-open No. 2000-173961, for example). By causing a cutting blade to cut into the wafer and removing the chamfered portion, the outer edge portion of the wafer does not become sharp and brittle even when the wafer is ground from the back surface side.

Incidentally, in a case in which a chamfered portion of a thick workpiece having a structure in which a plurality of wafers are bonded is to be removed completely by edge trimming, the cutting blade significantly wears, so that the lifespan thereof becomes extremely short. For such a reason, in processing a thick workpiece by edge trimming, in many cases, the chamfered portion of the workpiece is not removed completely in a thickness direction of the workpiece, with a part thereof on the back surface side left unremoved.

### SUMMARY OF THE INVENTION

A surface (hereinafter referred to as a processed surface) processed in the chamfered portion (hereinafter referred to as a trimmed portion) left after the edge trimming described above has such roughness that corresponds, for example, to the size of the abrasive grains included in the cutting blade, and typically has a certain level of coarseness. Hence, foreign matter such as debris generated during processing of the workpiece easily adheres to the processed surface of the trimmed portion. In addition, there is another problem that, in a case where a film is to be formed on the workpiece at a subsequent step, the film easily peels off from the processed surface of the trimmed portion.

To avoid these problems, edge trimming using a cutting blade including small-sized abrasive grains is one effective way of smoothing the processed surface of the trimmed portion and thus preventing foreign matter from adhering to the processed surface and the film from peeling off from the processed surface to some extent. In this case, however, since the small-sized abrasive grains make it more difficult to cut the workpiece, the cutting blade easily wears. This also results in a shorter lifespan of the cutting blade.

Accordingly, it is an object of the present invention to provide a new workpiece processing method and a new processing apparatus by which the possibility that foreign matter adheres to the trimmed portion and a film peels off from the trimmed portion can be reduced.

In accordance with a first aspect of the present invention, there is provided a workpiece processing method including holding a workpiece having a structure in which a first substrate is bonded to a second substrate, such that a side of the second substrate is held by an upper surface of a chuck table, after the holding, forming a trimmed portion along an outer edge of the workpiece by, while causing a ring-shaped cutting blade having an outer peripheral surface and a side surface to rotate, causing the rotating cutting blade to cut into the workpiece along the outer edge of the workpiece from a side of the first substrate to such a depth that the cutting blade reaches the second substrate, the trimmed portion having a bottom surface with which the outer peripheral surface of the cutting blade has been in contact and a side surface with which the side surface of the cutting blade has been in contact, and polishing the bottom surface and the side surface of the trimmed portion by using a polishing pad.

In the polishing, while the polishing pad that is in a disk shape and has an outer peripheral surface and a bottom surface is caused to rotate, the bottom surface of the rotating polishing pad may be brought into contact with the bottom surface of the trimmed portion, and the outer peripheral surface of the rotating polishing pad may be brought into contact with the side surface of the trimmed portion.

Further, the height of the outer peripheral surface of the polishing pad may be greater than the height of the side surface of the trimmed portion, the diameter of the bottom surface of the polishing pad may be larger than the width of the bottom surface of the trimmed portion, and, in the polishing, the polishing pad may be pressed against the bottom surface and the side surface of the trimmed portion.

In addition, the workpiece processing method may further include, after the trimming, holding the workpiece such that the side of the second substrate is exposed and cleaning the side of the second substrate of the workpiece, and the polishing may be performed while the cleaning is being performed.

Moreover, the workpiece processing method may further include, after the polishing, forming a film on the bottom surface of the trimmed portion.

In accordance with a second aspect of the present invention, there is provided a processing apparatus including a chuck table having an upper surface that is able to hold a workpiece having a structure in which a first substrate is bonded to a second substrate, such that a side of the second substrate is held by the upper surface, a rotational mechanism configured to cause the chuck table to rotate about an axis intersecting a plane including the upper surface, a cutting mechanism having a rotational axis to which a ring-shaped cutting blade having an outer peripheral surface and a side surface is mounted, and a polishing part to which a polishing pad for polishing a bottom surface and a side surface of a trimmed portion formed along an outer edge of the workpiece by the cutting mechanism is mounted, the bottom surface of the trimmed portion having been in contact with the outer peripheral surface of the cutting blade, and the side surface of the trimmed portion having been in contact with the side surface of the cutting blade.

In the processing apparatus, the polishing part may have a rotational axis to which a polishing pad that is in a disk shape and has an outer peripheral surface and a bottom surface is mounted, and, while the polishing pad is caused to rotate, the bottom surface of the rotating polishing pad may be brought into contact with the bottom surface of the trimmed portion, and the outer peripheral surface of the rotating polishing pad may be brought into contact with the side surface of the trimmed portion.

Further, the processing apparatus may further include a moving mechanism configured to move the polishing part in such a manner that the polishing pad is pressed against the bottom surface and the side surface of the trimmed portion, the height of the outer peripheral surface of the polishing pad may be greater than the height of the side surface of the trimmed portion, and the diameter of the bottom surface of the polishing pad may be larger than the width of the bottom surface of the trimmed portion.

In addition, the processing apparatus may further include a holding part configured to hold the workpiece such that the side of the second substrate is exposed, and a cleaning part configured to clean the side of the second substrate of the workpiece.

With the workpiece processing method according to the first aspect of the present invention and the processing apparatus according to the second aspect of the present invention, the bottom surface and the side surface of the trimmed portion formed in the workpiece are polished by the polishing pad, so that the bottom surface and the side surface of the trimmed portion are made smoother than in a case in which they are not polished by the polishing pad.

Hence, foreign matter is less likely to adhere to the trimmed portion and a film is less likely to peel off from the trimmed portion than in the case in which the bottom surface and the side surface of the trimmed portion are not polished. Therefore, with the workpiece processing method according to the first aspect of the present invention and the processing apparatus according to the second aspect of the present invention, it is possible to reduce the possibility that foreign matter adheres to the trimmed portion and a film peels off from the trimmed portion.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating a processing apparatus;

FIG. 2 is a cross-sectional view schematically illustrating a workpiece;

FIG. 3 is a perspective view schematically illustrating a chuck table and the like;

FIG. 4 is a perspective view schematically illustrating a lower surface cleaning mechanism and the like;

FIG. 5 is a side view schematically illustrating an outer edge polishing mechanism and the like;

FIG. 6 is a side view schematically illustrating a state in which a workpiece is held by the chuck table;

FIG. 7 is a side view schematically illustrating a state in which a cutting blade has cut into the workpiece;

FIG. 8 is a side view schematically illustrating a state in which a lower surface side of the workpiece is being cleaned and a trimmed portion is being polished; and

FIG. 9 is a cross-sectional view schematically illustrating the workpiece having a film formed on a first substrate side thereof.

### DETAILED DESCRIPTION OF THE PREFERRED EMBODIMENT

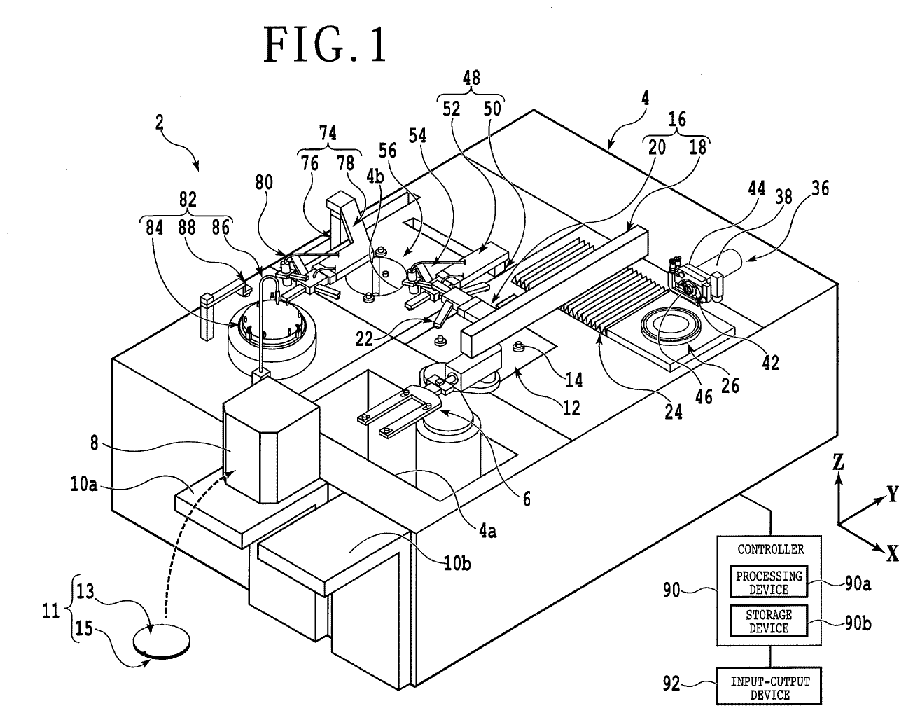

Description will hereinafter be made of an embodiment of the present invention with reference to the accompanying drawings. FIG. 1 is a perspective view illustrating a processing apparatus 2 according to the present embodiment. It is to be noted that, in FIG. 1, several constituent elements are represented in the form of a functional block. Further, an X-axis (left-right axis), a Y-axis (front-rear axis), and a Z-axis (up-down axis) used in the description below are perpendicular to one another.

As illustrated in FIG. 1, the processing apparatus 2 includes a base 4 that supports various elements constituting the processing apparatus 2. The base 4 has, at a front end side of an upper surface thereof, a recessed accommodation portion 4a an upper end of which is open on the upper surface of the base 4, and a robot arm 6 for use in conveying a platelike workpiece 11 or the like is accommodated in the accommodation portion 4a.

It is to be noted that the robot arm 6 is capable of conveying the workpiece 11 and, also, turning the workpiece 11 upside down.

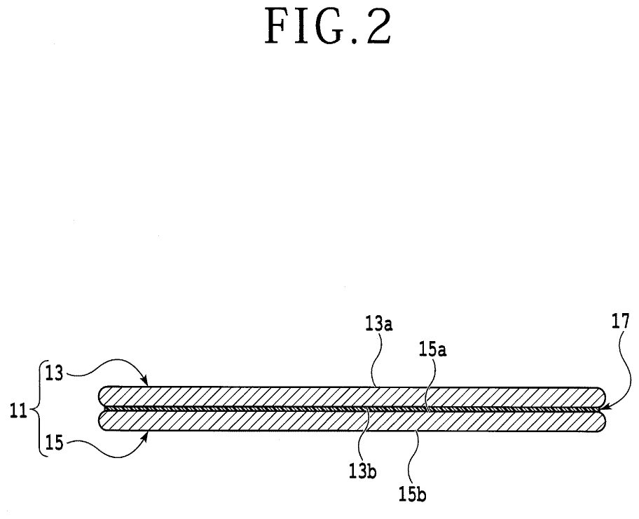

FIG. 2 is a cross-sectional view schematically illustrating the workpiece 11. The workpiece 11 used in the present embodiment is what is generally called a bonded substrate (bonded wafer) obtained, for example, by bonding two substrates (wafers) each formed of a semiconductor such as silicon with each other. More specifically, the workpiece 11 includes a disk-shaped first substrate (first wafer) 13 whose outer edge portion is chamfered and a disk-shaped second substrate (second wafer) 15 whose outer edge portion is chamfered.

The first substrate 13 has a circular first surface 13a and a circular second surface 13b on a side opposite to the first surface 13a. The second substrate 15 has a circular first surface 15a and a circular second surface 15b on a side opposite to the first surface 15a. The first substrate 13 is substantially the same in size as the second substrate 15. The disk-shaped workpiece 11 used in the present embodiment is formed, for example, by bonding the second surface 13b side of the first substrate 13 with the first surface 15a side of the second substrate 15 with an adhesive layer 17 interposed therebetween.

On each of the first substrate 13 and the second substrate 15, a plurality of devices typified by ICs are provided. Yet, there are no limitations on the kind, quantity, shape, structure, size, arrangement, and the like of the devices provided on the first substrate 13 and the second substrate 15. It is also possible that one of or both the first substrate 13 and the second substrate 15 have no devices provided thereon.

While the disk-shaped workpiece 11 exemplified in the present embodiment includes the two disk-shaped substrates that are each formed of a semiconductor such as silicon and are substantially the same in size, the material, quantity, shape, structure, size, and the like of the substrates included in the workpiece 11 are not limited to the example above. For example, two or more non-disk-shaped substrates that are formed of another semiconductor, ceramic, resin, metal, or the like and are different in size may be used for the workpiece 11.

Moreover, a protective member typified by a protective tape formed of a material such as resin may be attached to the first surface 13a of the first substrate 13 or the second surface 15b of the second substrate 15 exposed in the workpiece 11. The protective member attached to the exposed first surface 13a or second surface 15b of the workpiece 11 protects the workpiece 11 from impact or the like that can be applied during processing of the workpiece 11.

As illustrated in FIG. 1, in front of the accommodation portion 4a, there are provided cassette tables 10a and 10b on which a cassette 8 capable of accommodating a plurality of workpieces 11 can be placed. On a rear side of the accommodation portion 4a, there is provided a position adjustment mechanism 12 for adjusting the position of the workpiece 11 taken out from the cassette 8.

The position adjustment mechanism 12 includes a position adjustment table (not illustrated) having an upper surface that lies substantially parallel to the X-axis and the Y-axis; and four pins 14 that are arranged around the position adjustment table and are movable by an actuator (not illustrated) such as an air cylinder. The workpiece 11 having been taken out from the cassette 8 by the robot arm 6 is placed on the upper surface of the position adjustment table of the position adjustment mechanism 12.

For example, by the four pins 14 of the position adjustment mechanism 12 being moved in respective directions approaching the position adjustment table, the workpiece 11 placed on the upper surface of the position adjustment table is adjusted such that the center thereof is located at a predetermined position in a plane lying substantially parallel to the upper surface. It is to be noted that the number of pins 14 included in the position adjustment mechanism 12 is not necessarily required to be four and may be any number equal to or larger than three.

A first conveyance mechanism 16 of a ball-screw type is provided above the position adjustment mechanism 12. The first conveyance mechanism 16 includes a ball screw (not illustrated) coupled to a rotational drive source such as a motor, a guide rail 18 elongated along the Y-axis, and a moving part 20 attached to the guide rail 18 in a slidably movable manner. When the rotational drive source is actuated to cause the ball screw to rotate, the moving part 20 moves along the guide rail 18, that is, along the Y-axis.

The moving part 20 is provided with an actuator (not illustrated) such as an air cylinder having a movable portion capable of moving along the Z-axis. To the movable portion of the actuator, a holding hand 22 capable of holding the workpiece 11 is fixed. Motive power of the actuator causes the holding hand 22 to move along the Z-axis together with the movable portion. The workpiece 11 having been adjusted in position by the position adjustment mechanism 12 is held by the holding hand 22 and conveyed by the first conveyance mechanism 16 to the rear side of the position adjustment mechanism 12.

On the rear side of the position adjustment mechanism 12, there is provided a chuck table moving mechanism 24 of a ball-screw type. The chuck table moving mechanism 24 includes a ball screw (not illustrated) coupled to a rotational drive source such as a motor, a guide rail (not illustrated) elongated along the X-axis, and a moving part (not illustrated) attached to the guide rail in a slidably movable manner. When the rotational drive source is actuated to cause the ball screw to rotate, the moving part moves along the guide rail, that is, along the X-axis.

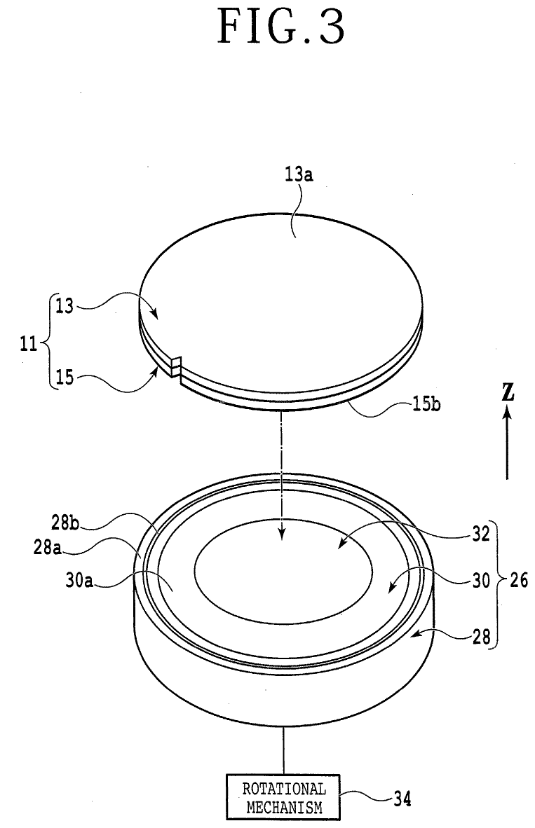

A chuck table 26 capable of holding the workpiece 11 is disposed above the moving part of the chuck table moving mechanism 24. FIG. 3 is a perspective view schematically illustrating the chuck table 26 and the like. It is to be noted that, in FIG. 3, one of constituent elements is represented in the form of a functional block.

As illustrated in FIG. 3, the chuck table 26 has a cylindrical annular supporting portion 28 formed of ceramic or the like. The workpiece 11 having been conveyed from the position adjustment mechanism 12 by the holding hand 22 and the first conveyance mechanism 16 is placed on an upper surface 28a of the annular supporting portion 28 such that the first substrate 13 side thereof faces upward.

The upper surface 28a side of the annular supporting portion 28 has a ring-shaped groove 28b formed along the upper surface 28a. The groove 28b is connected to a suction source (not illustrated) through a flow channel (not illustrated), a solenoid valve (not illustrated), and the like. When the solenoid valve is opened in a state in which the suction source is in operation, a negative pressure generated by the suction source acts on the groove 28b. This negative pressure causes suction-holding of the workpiece 11 supported by the upper surface 28a of the annular supporting portion 28. More specifically, an outer edge portion on the second substrate 15 side of the workpiece 11 is held by the upper surface 28a of the chuck table 26.

At a position inward of the annular supporting portion 28 and lower in height than the upper surface 28a, a disk-shaped base portion 30 is provided. In other words, the position of an upper surface 30a of the base portion 30 (position in a direction along the Z-axis) is lower than the position of the upper surface 28a of the annular supporting portion 28. A recess opening upward in a circular form is defined at the center of the base portion 30.

In the recess of the base portion 30, there is disposed a disk-shaped push-up part 32 that is enabled to move up and down along the Z-axis by an actuator (not illustrated) such as an air cylinder. When the push-up part 32 is caused to move upward in such a manner as to push up the workpiece 11 from below, it becomes easier to unload the workpiece 11 from the chuck table 26.

The chuck table 26 thus configured is supported by the moving part of the chuck table moving mechanism 24 through a rotational mechanism 34 including a motor and the like, and rotates, by motive power of the rotational mechanism 34, about a central axis (axis extending substantially parallel to the Z-axis) of the cylindrical annular supporting portion 28. In other words, the rotational mechanism 34 causes the chuck table 26 to rotate about an axis intersecting a virtual plane (flat plane) including the upper surface 28a of the annular supporting portion 28.

As illustrated in FIG. 1, a cutting mechanism 36 is disposed above the chuck table 26. The cutting mechanism 36 includes a spindle housing 38 that has, in its inside, an accommodation space elongated along the Y-axis. The spindle housing 38 is supported by a cutting-feed mechanism (not illustrated) of a ball-screw type.

The cutting-feed mechanism includes a ball screw (not illustrated) coupled to a rotational drive source such as a motor, a guide rail (not illustrated) elongated along the Z-axis, and a moving part (not illustrated) attached to the guide rail in a slidably movable manner. When the rotational drive source is actuated to cause the ball screw to rotate, the moving part moves along the guide rail, that is, along the Z-axis. The spindle housing 38 is fixed to the moving part and moves along the Z-axis together with the moving part.

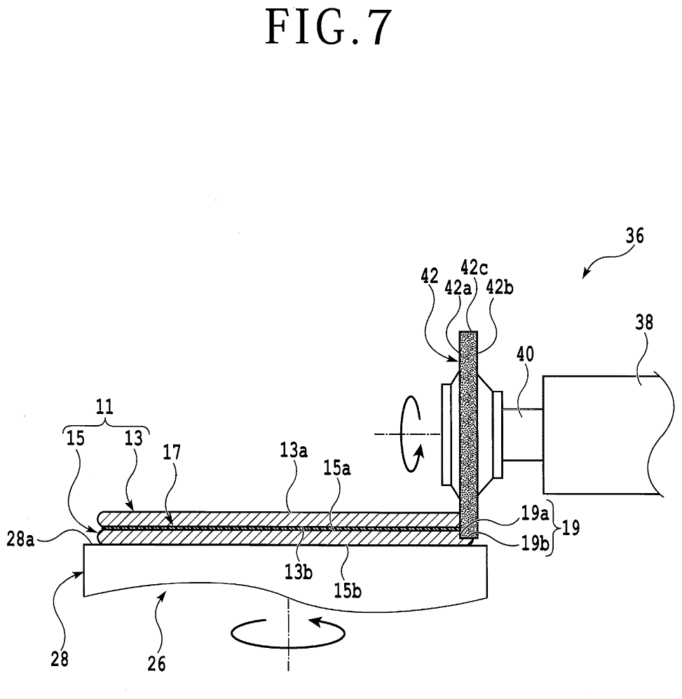

In the accommodation space inside the spindle housing 38, part of a columnar spindle 40 (refer to FIG. 7) that is to serve as a rotational axis extending along the Y-axis is accommodated. A rotational drive source (not illustrated) such as a motor is connected to a base end side of the spindle 40, and motive power of the rotational drive source causes the spindle 40 to rotate about its central axis extending along the Y-axis.

A tip end portion of the spindle 40 is exposed from the spindle housing 38, and a ring-shaped cutting blade 42 is mounted to the tip end portion of the spindle 40.

For example, the cutting blade 42 has a structure in which abrasive grains of diamond or the like are dispersed in a binder such as a vitrified bond, and this is suitable for processing (edge trimming) of an outer edge portion of the workpiece 11.

More specifically, the cutting blade 42 has a side surface 42a (refer to FIG. 7) and a side surface 42b (refer to FIG. 7) that lie substantially parallel to each other and an outer peripheral surface 42c (refer to FIG. 7) that connects an outer edge of the side surface 42a and an outer edge of the side surface 42b. The distance between the side surface 42a and the side surface 42b, that is, the width of the cutting blade 42 (width of the outer peripheral surface 42c), is typically in a range of 1 to 5 mm. However, the width of the cutting blade 42 (width of the outer peripheral surface 42c) may not necessarily fall within this range.

As illustrated in FIG. 1, a blade cover 44 capable of covering part of the cutting blade 42 mounted to the spindle 40 is provided at a tip end side of the spindle housing 38. At a lower portion of the blade cover 44, a pair of cutting nozzles 46 capable of supplying the cutting blade 42 with a liquid for cutting (cutting liquid) typified by water are disposed such that the cutting blade 42 is sandwiched by the cutting nozzles 46 along the Y-axis.

When the outer edge portion of the workpiece 11 held by the chuck table 26 is to be processed with the cutting blade 42, for example, the rotational drive source connected to the spindle 40 causes the cutting blade 42 to rotate together with the spindle 40, and the cutting-feed mechanism causes the cutting blade 42 to move downward along with the spindle housing 38. In addition, the rotational mechanism 34 causes the chuck table 26 to rotate. As a result, the rotating cutting blade 42 cuts into the outer edge portion of the workpiece 11, and the outer edge portion of the workpiece 11 is processed (edge trimmed).

A second conveyance mechanism 48 is provided at a lateral side of the chuck table moving mechanism 24. The second conveyance mechanism 48 includes a ball screw (not illustrated) coupled to a rotational drive source such as a motor, a guide rail (not illustrated) elongated along the X-axis, and a moving part 50 attached to the guide rail in a slidably movable manner. When the rotational drive source is actuated to cause the ball screw to rotate, the moving part 50 moves along the guide rail, that is, along the X-axis.

A base end portion of an arm part 52 is coupled to the moving part 50 through an actuator (not illustrated) such as an air cylinder and a rotational drive source (not illustrated) such as a motor. Motive power of the actuator causes the arm part 52 to move up and down along the Z-axis. Further, motive power of the rotational drive source causes the arm part 52 to rotate about an axis extending substantially parallel to the Z-axis.

In other words, a tip end portion of the arm part 52 turns about the base end portion of the arm part 52 in a plane that lies substantially perpendicularly to the Z-axis. It is to be noted that the range (angle) within which the arm part 52 can rotate is typically 90° or more. To the tip end portion of the arm part 52, a holding hand 54 capable of holding the workpiece 11 is fixed. The workpiece 11 that is held on the chuck table 26 and has been processed by the cutting mechanism 36 is held by the holding hand 54 and conveyed by the second conveyance mechanism 48.

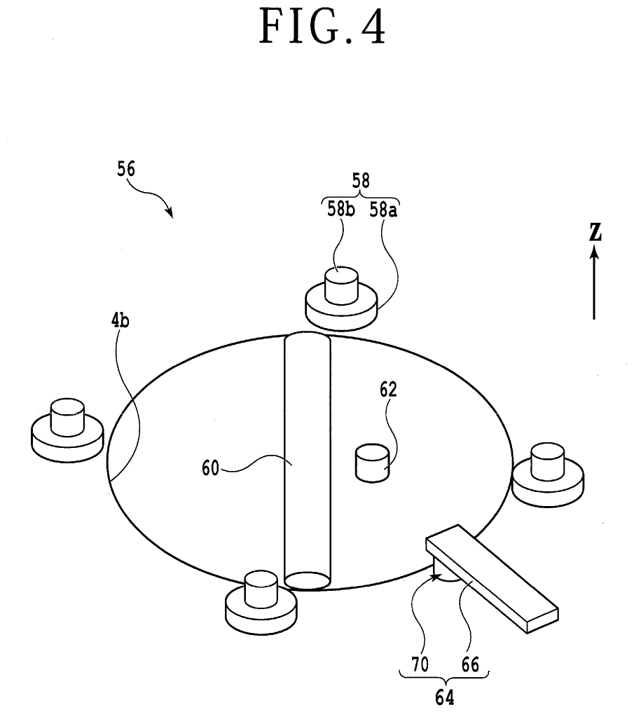

On a path of conveyance of the workpiece 11 by the second conveyance mechanism 48, a lower surface cleaning mechanism 56 is provided. FIG. 4 is a perspective view schematically illustrating the lower surface cleaning mechanism 56 and the like. As illustrated in FIG. 4, the lower surface cleaning mechanism 56 includes, for example, four holding parts 58 capable of holding the outer edge portion of the workpiece 11 from below. The four holding parts 58 are arranged at substantially equal intervals (at substantially equal angular intervals) in such a manner as to surround a circular, recessed accommodation portion 4b that is open on the upper surface of the base 4. It is to be noted that the number of holding parts 58 included in the lower surface cleaning mechanism 56 is not necessarily required to be four and may be any number equal to or larger than three.

Each of the holding parts 58 has, for example, a disk-shaped first supporting portion 58a and a second supporting portion 58b protruding upward from the center of the first supporting portion 58a. The workpiece 11 having been conveyed by the second conveyance mechanism 48 is placed on an upper surface of the first supporting portion 58a such that the first substrate 13 side faces upward. It is to be noted that only the outer edge portion of the second surface 15b of the second substrate 15 makes contact with the upper surface of the first supporting portion 58a; the other portions of the workpiece 11 make no contact with the upper surface.

The second supporting portion 58b is in the form of a column smaller in diameter than the first supporting portion 58a. The second supporting portion 58b has a side surface with which the outer edge of the workpiece 11 placed on the upper surface of the first supporting portion 58a is brought into contact. Accordingly, the holding parts 58 are capable of holding the workpiece 11 only at the outer edge portion of the workpiece 11. Hence, in the state in which the workpiece 11 is held by the holding parts 58, the portion of the workpiece 11 except the outer edge portion, for example, the second substrate 15 side (lower surface side) of the workpiece 11, is exposed.

Each holding part 58 is, for example, coupled to a rotational drive source (not illustrated) such as a motor, and rotates, by motive power of the rotational drive source, about a central axis of the second supporting portion 58b, that is, about an axis extending substantially parallel to the Z-axis. When the holding parts 58 are caused to rotate, also the workpiece 11 held by the holding parts 58 rotates about an axis extending substantially parallel to the Z-axis.

In the accommodation portion 4b, a lower surface cleaning tool (cleaning part) 60 that is in the form of a column elongated in a direction substantially perpendicular to the Z-axis is disposed in such a manner as to be able to make contact, from below, with the workpiece 11 held by the holding parts 58. That is, the lower surface cleaning tool 60 makes contact with the exposed second substrate 15 side of the workpiece 11 from below. The lower surface cleaning tool 60 is, for example, in the form of a brush using fibers made of resin such as polyamide and is thus suitable for cleaning the second substrate 15 side (lower surface side) of the workpiece 11.

An end portion of the lower surface cleaning tool 60 is, for example, coupled to a rotational drive source (not illustrated) such as a motor. Motive power of the rotational drive source causes the lower surface cleaning tool 60 to rotate about a central axis of the lower surface cleaning tool 60, that is, about an axis extending in a direction substantially perpendicular to the Z-axis. Further, at a position adjacent to the lower surface cleaning tool 60 in the accommodation portion 4b, there is disposed a lower surface cleaning nozzle (cleaning part) 62 capable of jetting upward a liquid for cleaning (cleaning liquid) typified by water.

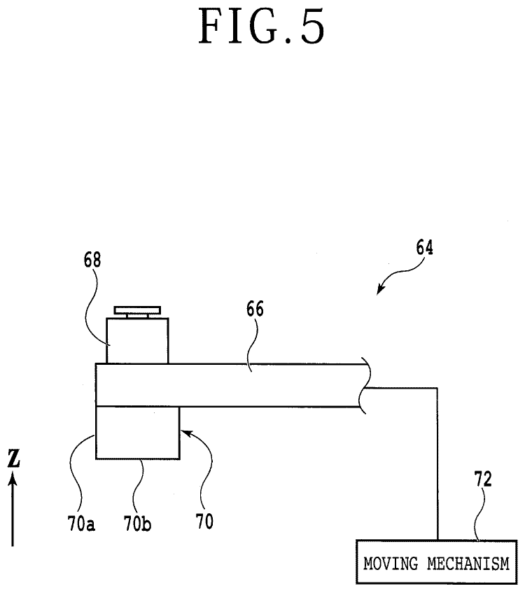

On a lateral side of the holding parts 58, there is disposed an outer edge polishing mechanism (polishing part) 64 for polishing the outer edge portion of the workpiece 11 having been processed by the cutting mechanism 36. FIG. 5 is a side view schematically illustrating the outer edge polishing mechanism 64 and the like. It is to be noted that, in FIG. 5, one of constituent elements is represented in the form of a functional block. As illustrated in FIG. 5, the outer edge polishing mechanism 64 includes an arm part 66 elongated in a direction substantially perpendicular to the Z-axis.

At an upper portion on a tip end side of the arm part 66, there is provided a rotational drive source 68 such as a motor having a rotational axis extending along the Z-axis. The rotational axis of the rotational drive source 68 has its tip end portion, for example, at a position below the arm part 66, and a disk-shaped (columnar) polishing pad 70 having an outer peripheral surface 70a and a bottom surface 70b is mounted to the tip end portion of the rotational axis. The polishing pad 70 is, for example, formed of a non-woven fabric or polymeric foam and does not contain abrasive grains. In an alternative configuration, the polishing pad 70 may contain abrasive grains.

A moving mechanism 72 is connected to a base end portion of the arm part 66. The moving mechanism 72 includes, for example, two sets of actuators typified by air cylinders and causes the arm part 66 to move in a direction substantially parallel to the Z-axis and in a direction substantially perpendicular to the Z-axis. More specifically, the moving mechanism 72 can cause the arm part 66 to move between a polishing position at which the polishing pad 70 makes contact with the outer edge portion of the workpiece 11 and a retracting position at which the polishing pad 70 is separated sufficiently away from the workpiece 11.

It is to be noted that the moving mechanism 72 may include actuators of a ball-screw type exemplified by the first conveyance mechanism 16 and the like, in place of or in addition to the actuators typified by air cylinders.

In the state in which the arm part 66 is located at the retracting position, the polishing pad 70 is, for example, immersed in a liquid for polishing (polishing liquid) stored in a container (not illustrated). The polishing pad 70 is thus externally supplied with the polishing liquid suitable for polishing the workpiece 11. In the case in which the workpiece 11 is mainly formed of silicon, for example, slurry in which silica abrasive grains are dispersed in an alkali aqueous solution of sodium hydroxide or the like is used as the polishing liquid.

It is to be noted that another method may be used to supply the polishing pad 70 with the polishing liquid. For example, the outer edge polishing mechanism 64 may have a supply path for supplying the polishing pad 70 with a polishing liquid. Alternatively, in a case in which the polishing pad 70 itself already holds a sufficient amount of polishing liquid, there is no need to externally supply the polishing pad 70 with a polishing liquid.

When the outer edge portion of the workpiece 11 is to be polished, for example, the rotational drive source coupled to the holding parts 58 causes the workpiece 11 to rotate along with the holding parts 58. Then, the moving mechanism 72 causes the arm part 66 to move from the retracting position to the polishing position, and the rotational drive source 68 causes the polishing pad 70 to rotate. Accordingly, the outer peripheral surface 70a and the bottom surface 70b of the rotating polishing pad 70 are brought into contact with the outer edge portion of the rotating workpiece 11, so that the outer edge portion of the workpiece 11 is polished.

As illustrated in FIG. 1, on a lateral side of the lower surface cleaning mechanism 56 and the outer edge polishing mechanism 64, there is provided a third conveyance mechanism 74. The third conveyance mechanism 74 includes a ball screw (not illustrated) coupled to a rotational drive source such as a motor, a guide rail (not illustrated) elongated along the Y-axis, and a moving part 76 attached to the guide rail in a slidably movable manner. When the rotational drive source is actuated to cause the ball screw to rotate, the moving part 76 moves along the guide rail, that is, along the Y-axis.

A base end portion of an arm part 78 is coupled to the moving part 76 through an actuator (not illustrated) such as an air cylinder. Motive power of the actuator causes the arm part 78 to move up and down along the Z-axis. A holding hand 80 capable of holding the workpiece 11 is fixed to a tip end portion of the arm part 78. The workpiece 11 having been cleaned on the second substrate 15 side thereof by the lower surface cleaning mechanism 56 and polished at the outer edge portion thereof by the outer edge polishing mechanism 64 is held by the holding hand 80 and conveyed forward by the third conveyance mechanism 74.

In front of the lower surface cleaning mechanism 56 and the outer edge polishing mechanism 64, there is provided an upper surface cleaning mechanism 82. The upper surface cleaning mechanism 82 includes a spinner table 84 capable of holding the workpiece 11. The spinner table 84 is supported on the base 4 through a rotational mechanism (not illustrated) including a motor and the like, and rotates, by motive power of the rotational mechanism, about an axis extending substantially parallel to the Z-axis. The workpiece 11 having been conveyed by the third conveyance mechanism 74 is placed on an upper surface of the spinner table 84 such that the first substrate 13 side faces upward.

An upper surface cleaning nozzle 86 capable of jetting downward a liquid for cleaning (cleaning liquid) typified by water is disposed above the spinner table 84.

Further, above the spinner table 84, there is also provided an upper surface cleaning tool 88 capable of making contact with the first substrate 13 side (upper surface side) of the workpiece 11 held by the spinner table 84 and cleaning the first substrate 13 side.

The upper surface cleaning tool 88 is, for example, a disk-shaped sponge member formed of resin such as polyvinyl alcohol (PVA) and has high flexibility and a high water absorption property. The upper surface cleaning tool 88 is coupled to an actuator (not illustrated) such as an air cylinder and a rotational drive source (not illustrated) such as a motor through an arm part.

Thus, the upper surface cleaning tool 88, by moving up and down along the Z-axis by motive power of the actuator and rotating (turning), by motive power of the rotational drive source, about an axis extending substantially parallel to the Z-axis, can clean the first substrate 13 side of the workpiece 11. The workpiece 11 having been cleaned by the upper surface cleaning mechanism 82 is then loaded into the cassette 8 by the robot arm 6.

A controller (control unit) 90 is connected to each element of the processing apparatus 2. The controller 90 is, for example, formed by a computer including a processing device 90a and a storage device 90b and controls the above-described operations and the like of the respective elements of the processing apparatus 2 such that the workpiece 11 is processed appropriately.

The processing device 90a is typically a central processing unit (CPU) and performs various kinds of processing necessary for controlling the above-described elements. The storage device 90b includes, for example, a main storage device such as a dynamic random access memory (DRAM) and an auxiliary storage device such as a hard disk drive or a flash memory. Functions of the controller 90 are realized, for example, by the processing device 90a operating in accordance with a program stored in the storage device 90b.

An input-output device 92 serving as a user interface is connected to the controller 90. The input-output device 92 is, for example, a touch screen and inputs an instruction given by an operator, to the controller 90. The input-output device 92 also outputs (in the case of a touch screen, displays) information regarding the processing apparatus 2 in a manner recognizable to the operator, on the basis of an instruction from the controller 90.

It is to be noted that, while the input-output device 92 described in the present embodiment has both the inputting function and the outputting function, an input device having the inputting function and an output device having the outputting function may each be connected to the controller 90. Examples of the input device that may be employed include a keyboard, a mouse, and the like. Examples of the output device that may be employed include a display device such as a liquid crystal display, a speaker capable of transmitting information by sound, an indicator light capable of transmitting information by color of light or a light emission state (emission, blinking, lighting-off, or the like), and the like.

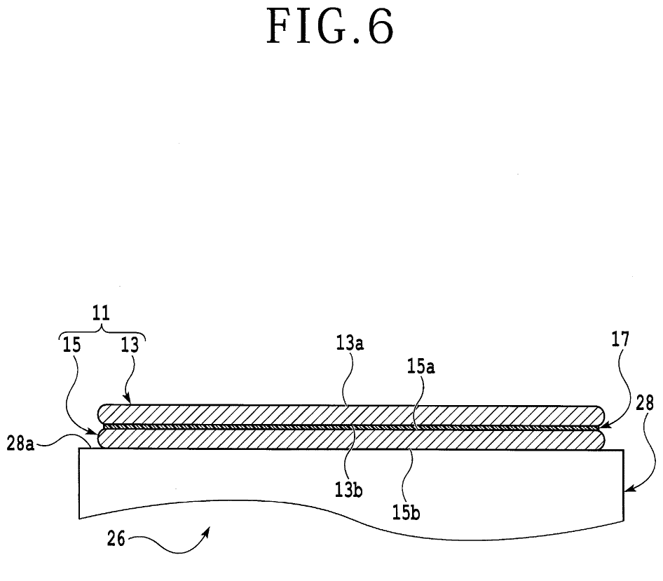

Description will next be made of a workpiece processing method performed using the processing apparatus 2 described above. In the workpiece processing method according to the present embodiment, first, the second substrate 15 side of the workpiece 11 described above is held by the upper surface 28a of the chuck table 26 (holding step). FIG. 6 is a side view schematically illustrating a state in which the workpiece 11 is held by the chuck table 26. It is to be noted that FIG. 6 illustrates a cross section of the workpiece 11 for the convenience of explanation.

Specifically, the workpiece 11 having been taken out from the cassette 8 is, for example, adjusted in position by the position adjustment mechanism 12 and is then placed on the chuck table 26 such that the second substrate 15 side thereof faces downward as illustrated in FIG. 6. Thereafter, when the solenoid valve is opened to cause a negative pressure generated by the suction source to act on the groove 28b, the workpiece 11 is held under suction by the chuck table 26.

After the second substrate 15 side of the workpiece 11 is held by the upper surface 28a of the chuck table 26, the outer edge portion of the workpiece 11 is processed (edge trimmed) by the cutting blade 42 (trimming step). FIG. 7 is a side view schematically illustrating a state in which the cutting blade 42 has cut into the workpiece 11. It is to be noted that, in FIG. 7 as well, a cross section of the workpiece 11 is illustrated for the convenience of explanation.

Specifically, first, the chuck table moving mechanism 24 causes the chuck table 26 to move such that the outer edge portion of the workpiece 11 is positioned directly below the cutting blade 42. Then, the cutting mechanism 36 causes the ring-shaped cutting blade 42 having the side surface 42a, the side surface 42b, and the outer peripheral surface 42c to rotate. In this state, the cutting-feed mechanism causes the cutting blade 42 to move downward along with the spindle housing 38.

As a result, the rotating cutting blade 42 cuts into the workpiece 11 from the first substrate 13 side. For example, when the amount of downward movement of the cutting blade 42 reaches a certain cutting-feed amount, the cutting-feed mechanism stops the downward movement of the cutting blade 42. Thereafter, as illustrated in FIG. 7, the rotational mechanism 34 causes the workpiece 11 to rotate along with the chuck table 26. The amount of rotation of the workpiece 11 caused by the rotational mechanism 34 is one turn (one revolution) or more.

Through the above operations, the rotating cutting blade 42 cuts into the workpiece 11 from the first substrate 13 side along the outer edge of the workpiece 11, so that the outer edge portion of the workpiece 11 is processed. Accordingly, along the outer edge of the workpiece 11, there is formed a trimmed portion 19 having a side surface 19a with which the one side surface 42a of the cutting blade 42 has been in contact and a bottom surface 19b with which the outer peripheral surface 42c of the cutting blade 42 has been in contact.

In a case in which the first substrate 13 included in the workpiece 11 is thick, the above operations are repeated. More specifically, the downward movement of the cutting blade 42 and the rotation of the workpiece 11 are alternately repeated until a lower end of the cutting blade 42 reaches the second substrate 15. That is, the cutting blade 42 cuts into the workpiece 11 from the first substrate 13 side to such a depth that the cutting blade 42 reaches the second substrate 15.

It is to be noted that, while the downward movement of the cutting blade 42 and the rotation of the workpiece 11 are performed at timings different from each other in the present embodiment, these may be performed at the same timing. Specifically, during the rotation of the workpiece 11 along with the chuck table 26 caused by the rotational mechanism 34, the cutting-feed mechanism may cause the rotating cutting blade 42 to move downward along with the spindle housing 38. In this case as well, the downward movement of the cutting blade 42 caused by the cutting-feed mechanism is continued until the lower end of the cutting blade 42 reaches the second substrate 15.

In the present embodiment, the height of the side surface 19a of the trimmed portion 19 (length along the thickness direction of the workpiece 11) is approximately 0.01 to 1.0 mm, for example. The width of the bottom surface 19b of the trimmed portion 19 (length along a radial direction of the workpiece 11) is approximately 0.1 to 10 mm, for example. However, the height of the side surface 19a of the trimmed portion 19 and the width of the bottom surface 19b of the trimmed portion 19 may not necessarily fall within the above ranges.

After the outer edge portion of the workpiece 11 is processed by the cutting blade 42 and the trimmed portion 19 is formed, for example, the second substrate 15 side of the workpiece 11 is cleaned (cleaning step). In addition, in the present embodiment, while the second substrate 15 side of the workpiece 11 is being cleaned, the side surface 19a and the bottom surface 19b of the trimmed portion 19 are polished by the polishing pad 70 (polishing step).

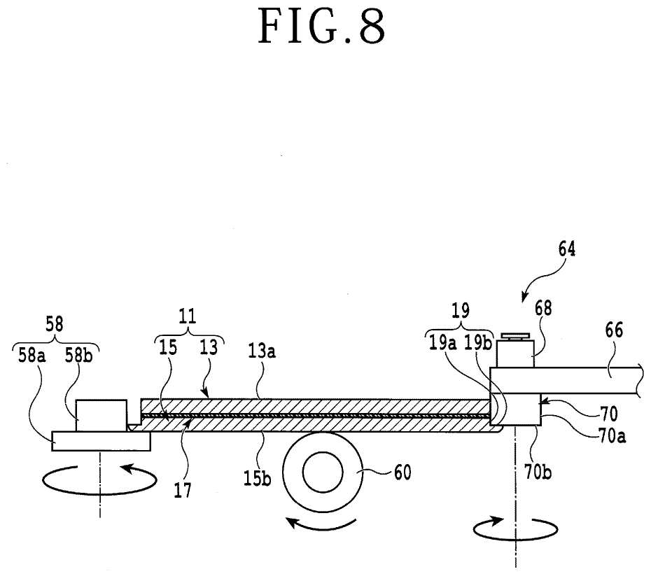

FIG. 8 is a side view schematically illustrating a state in which the lower surface side (second substrate 15 side) of the workpiece 11 is being cleaned and the trimmed portion 19 is being polished. It is to be noted that, in FIG. 8 as well, a cross section of the workpiece 11 is illustrated for the convenience of explanation.

Specifically, first, the workpiece 11 having been processed and unloaded from the chuck table 26 is placed on the plurality of holding parts 58 such that the second substrate 15 side thereof faces downward.

As described above, the holding parts 58 are capable of holding the workpiece 11 only at the outer edge portion of the workpiece 11. Hence, when the workpiece 11 is held by the holding parts 58, the second substrate 15 side (lower surface side) of the workpiece 11 is exposed, and the lower surface cleaning tool 60 makes contact with the exposed second substrate 15 side of the workpiece 11.

After the workpiece 11 has been held by the holding parts 58, as illustrated in FIG. 8, the rotational drive source coupled to the holding parts 58 causes the holding parts 58 to rotate, thereby causing the workpiece 11 to rotate. Meanwhile, a cleaning liquid is supplied from the lower surface cleaning nozzle 62 (FIG. 4) to the second substrate 15 side of the workpiece 11, and the rotational drive source coupled to the lower surface cleaning tool 60 causes the lower surface cleaning tool 60 to rotate.

As a result, the second substrate 15 side of the workpiece 11 is cleaned.

In addition, as described above, at the timing when the second substrate 15 side of the workpiece 11 is being cleaned, that is, at the timing when the workpiece 11 is rotating, the moving mechanism 72 causes the arm part 66 to move from the retracting position to the polishing position, and the rotational drive source 68 causes the polishing pad 70 to rotate. Accordingly, the outer peripheral surface 70a and the bottom surface 70b of the rotating polishing pad 70 are pressed against the side surface 19a and the bottom surface 19b of the trimmed portion 19, respectively, and the trimmed portion 19 is thus polished.

As illustrated in FIG. 8, the height of the outer peripheral surface 70a of the polishing pad 70 (length in the up-down direction or thickness of the polishing pad 70) is greater than the height of the side surface 19a of the trimmed portion 19 (length along the thickness direction of the workpiece 11) Further, the diameter of the bottom surface 70b of the polishing pad 70 (length in a horizontal direction or width of the polishing pad 70) is larger than the width of the bottom surface 19b of the trimmed portion 19 (length along the radial direction of the workpiece 11).

Hence, when the polishing pad 70 is pressed against the trimmed portion 19 in such a manner that a connection portion between the outer peripheral surface 70a and the bottom surface 70b of the polishing pad 70 is brought into contact with a connection portion between the side surface 19a and the bottom surface 19b of the trimmed portion 19 in the state in which the workpiece 11 is rotating, the whole of the side surface 19a and the bottom surface 19b of the trimmed portion 19 is polished by the polishing pad 70.

It is to be noted that, while there are no particular limitations on the height of the outer peripheral surface 70a of the polishing pad 70, the height of the outer peripheral surface 70a of the polishing pad 70 is preferably greater by 0.01 mm or more than the height of the side surface 19a of the trimmed portion 19 so that the entire side surface 19a of the trimmed portion 19 can surely be polished by the outer peripheral surface 70a of the polishing pad 70. Typically, the height of the outer peripheral surface 70a of the polishing pad 70, that is, the thickness of the polishing pad 70, is approximately 0.1 to 5.0 mm.

Similarly, while there are no particular limitations on the diameter of the bottom surface 70b of the polishing pad 70, the diameter of the bottom surface 70b of the polishing pad 70 is preferably larger by 0.01 mm or more than the width of the bottom surface 19b of the trimmed portion 19 so that the entire bottom surface 19b of the trimmed portion 19 can surely be polished by the bottom surface 70b of the polishing pad 70. Typically, the diameter of the bottom surface 70b of the polishing pad 70, that is, the width of the polishing pad 70, is approximately 10 to 30 mm.

Moreover, since the rotating disk-shaped (columnar) polishing pad 70 is pressed against the trimmed portion 19 of the rotating workpiece 11 in the present embodiment, the entire trimmed portion 19 is polished efficiently. The number of rotations (rotation speed) of the polishing pad 70 is, for example, equal to or more than 500 rpm but equal to or less than 1500 rpm, preferably, equal to or more than 800 rpm but equal to or less than 1000 rpm. The number of rotations (rotation speed) of the workpiece 11 is, for example, equal to or more than 50 rpm but equal to or less than 150 rpm, preferably, equal to or more than 80 rpm but equal to or less than 100 rpm. However, the number of rotations of the polishing pad 70 and the number of rotations of the workpiece 11 may not necessarily fall within the above ranges.

After the side surface 19a and the bottom surface 19b of the trimmed portion 19 have been made smooth, the polishing of the side surface 19a and the bottom surface 19b is ended. After the second substrate 15 side of the workpiece 11 has been made clean, the cleaning of the second substrate 15 side of the workpiece 11 is ended. It is to be noted that, for the purpose of sufficiently preventing adhesion of foreign matter to the side surface 19a and the bottom surface 19b of the trimmed portion 19 and peeling-off of a film from the bottom surface 19b of the trimmed portion 19, for example, the side surface 19a and the bottom surface 19b of the trimmed portion 19 are preferably polished to achieve an arithmetic mean roughness (Ra) of 1.0 μm or less, more preferably, 0.5 μm or less, based on the specification in JIS B 0601.

After the cleaning of the second substrate 15 side of the workpiece 11 and the polishing of the trimmed portion 19 have been completed, the workpiece 11 is unloaded from the holding parts 58 and loaded onto the spinner table 84 of the upper surface cleaning mechanism 82, for example. Thereafter, the workpiece 11 having been cleaned on the upper surface side (first substrate 13 side) thereof by the upper surface cleaning mechanism 82 is, for example, unloaded from the spinner table 84 by the robot arm 6 and loaded into the cassette 8.

As described above, with the workpiece processing method and the processing apparatus 2 according to the present embodiment, the side surface 19a and the bottom surface 19b of the trimmed portion 19 formed in the workpiece 11 are polished by the polishing pad 70, so that the side surface 19a and the bottom surface 19b of the trimmed portion 19 are made smoother than in a case in which they are not polished by the polishing pad 70.

Hence, foreign matter is less likely to adhere to the trimmed portion 19 and a film is less likely to peel off from the trimmed portion 19 than in the case in which the side surface 19a and the bottom surface 19b of the trimmed portion 19 are not polished. Therefore, with the workpiece processing method and the processing apparatus 2 according to the present embodiment, it is possible to reduce the possibility that foreign matter adheres to the trimmed portion 19 and a film peels off from the trimmed portion 19.

It is to be noted that the present invention is not limited to the contents of the embodiment described above and can be implemented in various modified forms. For example, after the side surface 19a and the bottom surface 19b of the trimmed portion 19 are polished in the workpiece processing method according to the above embodiment, an optional film may be formed on the first substrate 13 side of the workpiece 11 (on the first surface 13a of the first substrate 13 and the bottom surface 19b of the trimmed portion 19) (film forming step).

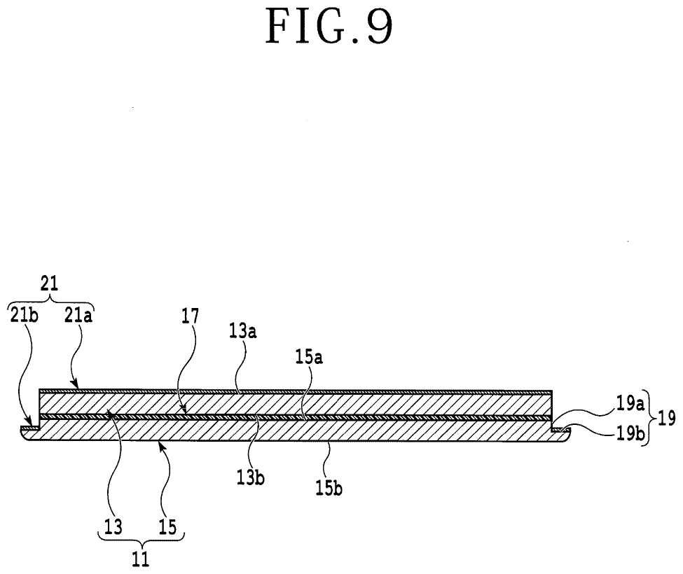

That is, the workpiece processing method according to the present invention may further include a procedure (film forming step) of forming a film on the bottom surface 19b of the trimmed portion 19 after a procedure (polishing step) of polishing the side surface 19a and the bottom surface 19b of the trimmed portion 19. FIG. 9 is a cross-sectional view schematically illustrating the workpiece 11 having a film 21 formed on the first substrate 13 side thereof.

The film 21 formed on the first substrate 13 side of the workpiece 11 is typically a conductor film, a semiconductor film, or an insulator film and includes a film 21a in close contact with the first surface 13a of the first substrate 13 and a film 21b in close contact with the bottom surface 19b of the trimmed portion 19 as illustrated in FIG. 9. Examples of the method for forming the film 21 include chemical vapor deposition (CVD) and physical vapor deposition (PVD).

The material of the film 21, the method for forming the film 21, the position where the film 21 is formed, and the like are not limited to the above examples. For example, the film 21 may be formed on the side surface 19a of the trimmed portion 19. In other words, the film 21 may include a portion in close contact with the side surface 19a of the trimmed portion 19.

In the workpiece processing method according to the present invention, the bottom surface 19b (and the side surface 19a) of the trimmed portion 19 is polished by the polishing pad 70 to be smooth, and hence, the film 21b formed on the bottom surface 19b (and the film formed on the side surface 19a) is less likely to peel off from the bottom surface 19b (and the side surface 19a). Accordingly, defects in devices that would otherwise be caused by the film 21b peeled off from the bottom surface 19b (and the side surface 19a) are reduced.

Further, while the side surface 19a and the bottom surface 19b of the trimmed portion 19 are polished during the cleaning of the second substrate 15 side of the workpiece 11 in the embodiment described above, the cleaning of the second substrate 15 side of the workpiece 11 and the polishing of the side surface 19a and the bottom surface 19b of the trimmed portion 19 may be performed at timings different from each other.

In this case, when the side surface 19a and the bottom surface 19b of the trimmed portion 19 are to be polished, the workpiece 11 may not necessarily be held in such a manner that the second substrate 15 side is exposed. For example, it is also possible that the side surface 19a and the bottom surface 19b of the trimmed portion 19 are polished in a state in which the second substrate 15 side of the workpiece 11 is held by the chuck table 26.

Furthermore, while the disk-shaped (columnar) polishing pad 70 is used to polish the side surface 19a and the bottom surface 19b of the trimmed portion 19 in the embodiment described above, a non-disk-shaped polishing pad, for example, a polishing pad in a rectangular parallelepiped shape, may be used to polish the trimmed portion 19. In this case, the height of a side surface of the polishing pad is greater than the height of the side surface 19a of the trimmed portion 19, and the width of the polishing pad is larger than the width of the bottom surface 19b of the trimmed portion 19.

Besides, the structures, methods, and the like of the embodiment and modifications described above can be implemented in various modified forms without departing from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A workpiece processing method comprising:
holding a workpiece having a structure in which a first substrate is bonded to a second substrate, such that a side of the second substrate is held by an upper surface of a chuck table;
after the holding, forming a trimmed portion along an outer edge of the workpiece by, while causing a ring-shaped cutting blade having an outer peripheral surface and a side surface to rotate, causing the rotating cutting blade to cut into the workpiece along the outer edge of the workpiece from a side of the first substrate to such a depth that the cutting blade reaches the second substrate, the trimmed portion having a bottom surface with which the outer peripheral surface of the cutting blade has been in contact and a side surface with which the side surface of the cutting blade has been in contact; and
polishing the bottom surface and the side surface of the trimmed portion by using a polishing pad.

2. The workpiece processing method according to claim 1, wherein,
in the polishing, while the polishing pad that is in a disk shape and has an outer peripheral surface and a bottom surface is caused to rotate, the bottom surface of the rotating polishing pad is brought into contact with the bottom surface of the trimmed portion, and the outer peripheral surface of the rotating polishing pad is brought into contact with the side surface of the trimmed portion.

3. The workpiece processing method according to claim 2, wherein
a height of the outer peripheral surface of the polishing pad is greater than a height of the side surface of the trimmed portion,
a diameter of the bottom surface of the polishing pad is larger than a width of the bottom surface of the trimmed portion, and,
in the polishing, the polishing pad is pressed against the bottom surface and the side surface of the trimmed portion.

4. The workpiece processing method according to claim 1, further comprising:
after the trimming, holding the workpiece such that the side of the second substrate is exposed and cleaning the side of the second substrate of the workpiece, wherein
the polishing is performed while the cleaning is being performed.

5. The workpiece processing method according to claim 2, further comprising:
after the trimming, holding the workpiece such that the side of the second substrate is exposed and cleaning the side of the second substrate of the workpiece, wherein
the polishing is performed while the cleaning is being performed.

6. The workpiece processing method according to claim 3, further comprising:
after the trimming, holding the workpiece such that the side of the second substrate is exposed and cleaning the side of the second substrate of the workpiece, wherein
the polishing is performed while the cleaning is being performed.

7. The workpiece processing method according to claim 1, further comprising:
after the polishing, forming a film on the bottom surface of the trimmed portion.

8. The workpiece processing method according to claim 2, further comprising:
after the polishing, forming a film on the bottom surface of the trimmed portion.

9. The workpiece processing method according to claim 3, further comprising:
after the polishing, forming a film on the bottom surface of the trimmed portion.

10. A processing apparatus comprising:
a chuck table having an upper surface that is able to hold a workpiece having a structure in which a first substrate is bonded to a second substrate, such that a side of the second substrate is held by the upper surface;
a rotational mechanism configured to cause the chuck table to rotate about an axis intersecting a plane including the upper surface;
a cutting mechanism having a rotational axis to which a ring-shaped cutting blade having an outer peripheral surface and a side surface is mounted; and
a polishing part to which a polishing pad for polishing a bottom surface and a side surface of a trimmed portion formed along an outer edge of the workpiece by the cutting mechanism is mounted, the bottom surface of the trimmed portion having been in contact with the outer peripheral surface of the cutting blade, and the side surface of the trimmed portion having been in contact with the side surface of the cutting blade.

11. The processing apparatus according to claim 10, wherein
the polishing part has a rotational axis to which a polishing pad that is in a disk shape and has an outer peripheral surface and a bottom surface is mounted, and,
while the polishing pad is caused to rotate, the bottom surface of the rotating polishing pad is brought into contact with the bottom surface of the trimmed portion, and the outer peripheral surface of the rotating polishing pad is brought into contact with the side surface of the trimmed portion.

12. The processing apparatus according to claim 11, further comprising:
a moving mechanism configured to move the polishing part in such a manner that the polishing pad is pressed against the bottom surface and the side surface of the trimmed portion, wherein
a height of the outer peripheral surface of the polishing pad is greater than a height of the side surface of the trimmed portion, and
a diameter of the bottom surface of the polishing pad is larger than a width of the bottom surface of the trimmed portion.

13. The processing apparatus according to claim 10, further comprising:
a holding part configured to hold the workpiece such that the side of the second substrate is exposed; and
a cleaning part configured to clean the side of the second substrate of the workpiece.

14. The processing apparatus according to claim 11, further comprising:
a holding part configured to hold the workpiece such that the side of the second substrate is exposed; and
a cleaning part configured to clean the side of the second substrate of the workpiece.

15. The processing apparatus according to claim 12, further comprising:
a holding part configured to hold the workpiece such that the side of the second substrate is exposed; and
a cleaning part configured to clean the side of the second substrate of the workpiece.
